(19) United States
(12) Patent Application Publication
(10) Pub. No.: US 2013/0130458 A1
(43) Pub. Date: May 23, 2013

(54) METHOD OF MANUFACTURING SEMICONDUCTOR DEVICE

(71) Applicant: SK hynix Inc., Icheon (KR)

(72) Inventor: Eun Sung LEE, Seoul (KR)

(73) Assignee: SK HYNIX INC., Icheon (KR)

(21) Appl. No.: 13/651,132

(22) Filed: Oct. 12, 2012

(30) Foreign Application Priority Data
Nov. 21, 2011 (KR) 10-2011-0121693

(51) Int. Cl. H01L 21/336

(52) U.S. Cl. 438/289; 257/E21.409

(57) ABSTRACT

A method of manufacturing a semiconductor device is provided. The method includes forming a gate pattern on a semiconductor substrate, performing a C ion implantation process for suppressing diffusion of dopants in the semiconductor substrate, and performing a halo ion implantation process including P ions. Therefore, a hot carrier effect due to change of a dopant profile and degradation caused by GIDL can be improved.

### CROSS-REFERENCES TO RELATED APPLICATION

The present application claims priority to Korean patent application number 10-2011-0121693 filed on Nov. 21, 2011, which is incorporated by reference in its entirety.

### BACKGROUND OF THE INVENTION

Embodiments of the present invention relate to a method of manufacturing a semiconductor device using a halo ion implantation process including phosphorus ions.

Semiconductor memory devices include a plurality of unit cells constituted of a capacitor and a transistor. The capacitor is used to store data temporarily and the transistor is used to transfer data between the capacitor and a bit line in response to a control signal (a word line) using a semiconductor property in which electric conductivity changes according to environment. The transistor is constituted of three parts: a gate, a source and a drain. Charges move between the source and drain according to the control signal input to the gate. The charges move between the source and drain through a channel region.

When a conventional transistor is fabricated on a semiconductor substrate, the gate is formed on the semiconductor substrate and then the source and drain are formed at both sides of the gate by implanting impurities into the semiconductor substrate. To increase data storage capacity and integration degree of semiconductor memory devices, there is a demand for fabricating the unit cells with a more scaled-down size. That is, the design rule of a capacitor and a transistor included in a unit cell is reduced, and thus a channel length of a cell transistor is reduced. However, this causes a short channel effect and drain induced barrier lowering (DIBL) to occur in the conventional transistor and thus the reliability of operation is degraded.

The phenomena caused by reduction of a channel length can be overcome if a threshold voltage is maintained so that the cell transistor performs a normal operation. Conventionally, as channel length is reduced, an impurity doping concentration in a region in which the channel region is to be formed is increased. As a result, the short channel effect caused by a reduction in a gate channel length may be a more difficult issue to resolve.

That is, if channel length is reduced to form a short channel below 0.5 μm, a depletion region of a source/drain extends into the channel. Thus, an effective channel length is reduced and a threshold voltage is reduced. Therefore, the short channel effect occurs, which may deteriorate a control function of the gate.

In highly integrated semiconductor devices, it is necessary for nano-grade devices to have increased speed, a low operation voltage of 1 to 2 V, and a low threshold voltage. However, if the threshold voltage is too low, it is difficult to control the semiconductor device due to the short channel effect. In addition, the short channel effect causes DIBL due to hot carriers.

In a PMOS transistor formed in a peripheral circuit region, electrons are incidentally generated by holes. The electrons are trapped in an isolation layer adjacent to a channel causing inversion in the channel of the PMOS transistor, thereby reducing an effective channel length. The channel inversion due to the electron trapping occurs at an edge of an active region adjacent to the isolation layer below a gate pattern.

As described above, undesired channel inversion in the PMOS transistor increases a leakage current in an off state and power consumption, and reduces operation speed and a breakdown voltage. This phenomenon is called hot electron induced punch-through (HEIP).

### SUMMARY

According to one aspect of an exemplary embodiment, a method of manufacturing a semiconductor device includes forming a gate pattern on a semiconductor substrate, implanting carbon (C) ions into the semiconductor substrate, and implanting halo ions into the semiconductor substrate. In an embodiment, implanting the halo ions is performed in a tilted ion implantation process.

The implanting the C ions may include performing an ion implantation process using a dose of 1×10¹⁴ to 1×10¹⁵ ions/cm² and a beam energy of 1 to 15 keV.

The implanting the C ions may include performing a tilted ion implantation process at an angle of 0 to 20 degrees with respect to a direction orthogonal to the semiconductor substrate.

The implanting the halo ions may include implanting phosphorus (P) ions.

The implanting the halo ions may include performing an ion implantation process using a dose of 1×10¹² to 1×10¹⁴ ions/cm² and a beam energy of 10 to 100 keV.

The implanting the halo ions may include performing a tilted ion implantation process at an angle of 0 to 20 degrees with respect to a direction orthogonal to the semiconductor substrate.

These and other features, aspects, and embodiments are described below in the section entitled “DESCRIPTION OF EXEMPLARY EMBODIMENT.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1A to 1C are cross-sectional views illustrating a method of manufacturing a semiconductor device according to an exemplary embodiment of the present invention;

FIG. 2 is a graph showing a result obtained by a method of manufacturing a semiconductor device according to an exemplary embodiment of the present invention;

FIG. 3 is a block diagram illustrating a configuration of a cell array according to an exemplary embodiment of the present invention;

FIG. 4 is a block diagram illustrating a configuration of a semiconductor device according to an exemplary embodiment of the present invention;

FIG. 5 is a block diagram illustrating a configuration of a semiconductor module according to an exemplary embodiment of the present invention;

FIG. 6 is a block diagram illustrating a configuration of a semiconductor system according to an exemplary embodiment of the present invention; and

FIG. 7 is a block diagram illustrating configurations of an electronic unit and an electronic system according to an exemplary embodiment of the present invention.

### DESCRIPTION OF EXEMPLARY EMBODIMENT

Exemplary embodiments of the present invention are described herein with reference to illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

Hereinafter, an exemplary embodiment of the present invention will be described in detail with reference to accompanying drawings.

In the exemplary embodiment of the present invention, to improve a short channel effect, a halo ion implantation process of implanting phosphorus (P) ions is performed when a PMOS transistor is fabricated, unlike a conventional method, which implants arsenic (AS) ions. The ion implantation process of implanting halo ions including P ions will be described in detail.

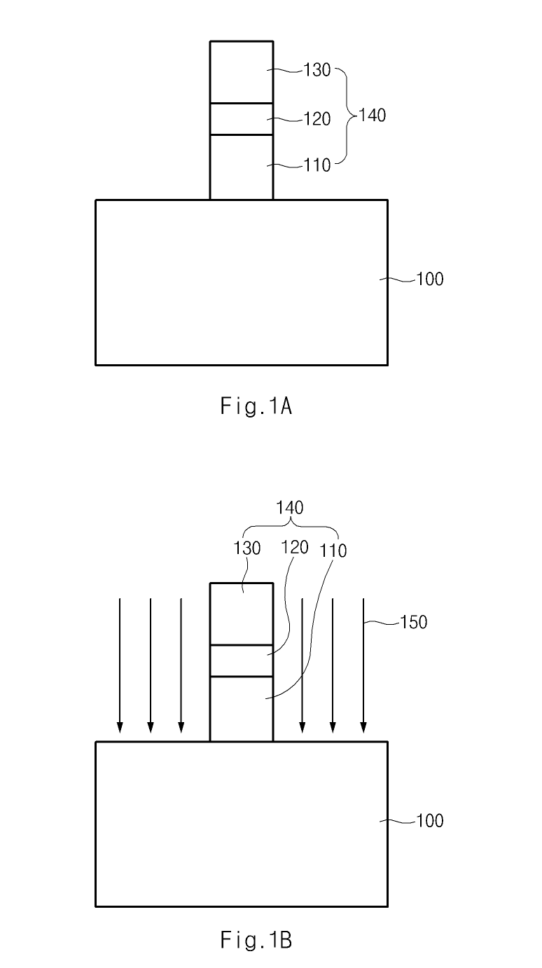

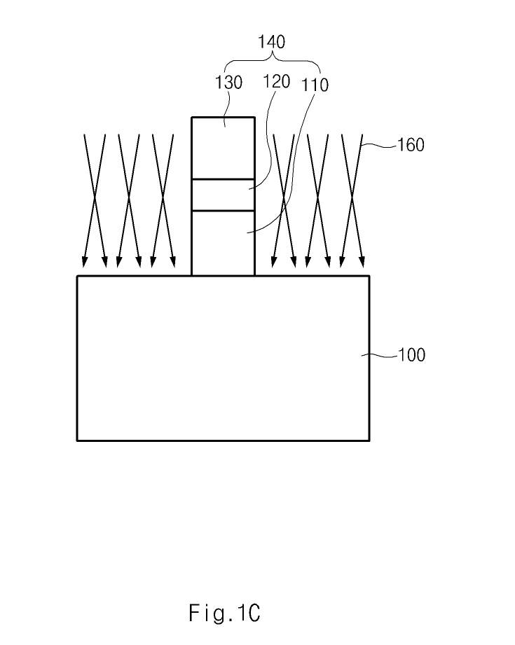

FIGS. 1A to 1C are cross-sectional views illustrating a method of manufacturing a semiconductor device according to an exemplary embodiment of the present invention.

Referring to FIG. 1A, a gate pattern 140 is formed on a semiconductor substrate 100. Here, the gate pattern 140 includes a gate oxide layer 110, a gate conductive layer 120, and a gate hard mask 130.

Referring to FIG. 1B, a carbon (C) ion implantation process 150 is performed on the exposed semiconductor substrate 100. In an embodiment, the C ion implantation process 150 may be performed with a dose of 1×10¹⁴ to 1×10¹⁵ ions/cm² and a beam energy of 1 to 15 keV. The C ion implantation process 150 may be performed through a tilted ion implantation process, which may be performed at an angle of 0 to 20 degrees with respect to a direction orthogonal to the semiconductor substrate 100. The C ion implantation process 150 may be repeatedly performed. The C ion implantation process 150 may be performed by tilting the semiconductor substrate 100 at a predetermined angle or by rotating the semiconductor substrate 100 by a predetermined angle, e.g., by 90 degrees, so that the C ions are implanted uniformly into the semiconductor substrate 100.

Referring to FIG. 1C, a halo ion implantation process 160 is performed on the exposed semiconductor substrate 100. The halo ion implantation process 160 may include implanting P(Phosphorus) ions and may be performed with a dose of 1×10¹² to 1×10¹⁴ ions/cm² and a beam energy of 10 to 100 keV. the phosphorus ions are implanted into substantially all of the semiconductor substrate 100, except the semiconductor substrate 100 under the gate pattern 140 and the phosphorus ions are implanted into the semiconductor substrate 100 at substantially the same level as where the carbon (C) ions is implanted. The halo ion implantation process may be a tilted implantation process, which may be performed by implanting the halo ions at an angle of 0 to 20 degrees with respect to a direction orthogonal to the semiconductor substrate 100. The halo ion implantation process 160 may be repeatedly performed. The halo ion implantation process 160 may be performed by tilting the semiconductor substrate 100 at a predetermined angle or by rotating the semiconductor substrate 100, e.g., by 90 degrees, so that the halo ions are uniformly implanted into the semiconductor substrate. Through the above-described ion implantation process, the hot carrier effect, which results from a change in a dopant profile, and degradation caused by GIDL can be improved.

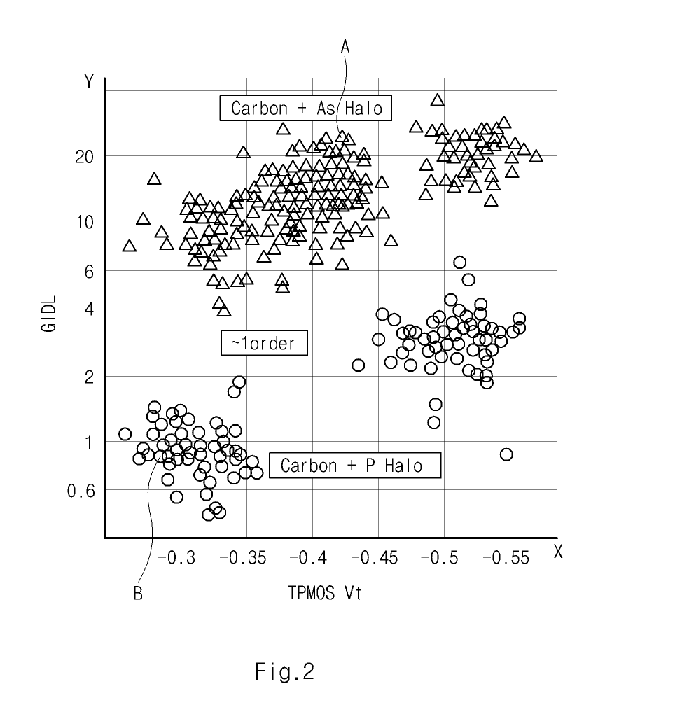

FIG. 2 is a graph showing a result obtained by a method of manufacturing a semiconductor device according to an exemplary embodiment of the present invention.

Referring to FIG. 2, the X-axis denotes a threshold voltage (Vt) and the Y-axis denotes a GIDL value. FIG. 2 illustrates a relationship between the threshold voltage and GIDL when the C ion implantation process and the halo ion implantation process including P ions according to the exemplary embodiment are performed, which is indicated by B, and a relationship between the threshold voltage and GIDL when a C implantation process and an As ion implantation process are performed according to a conventional method, which is indicated by A. As shown by A and B of FIG. 2, there is some difference in the threshold voltage between A and B in the X-axis, and GIDL is considerably improved in B compared to GIDL in A.

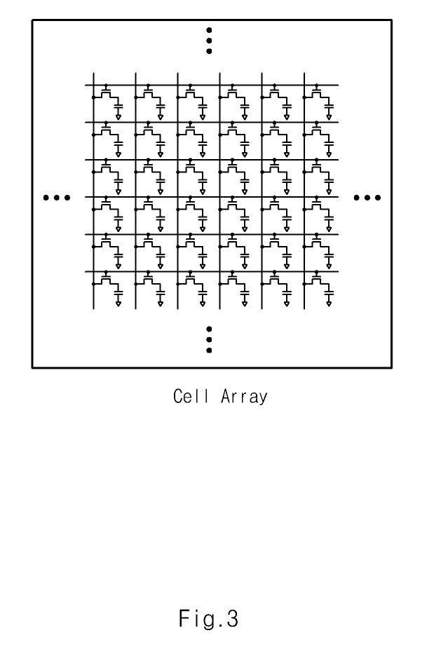

FIG. 3 is a block diagram illustrating a configuration of a cell array according to an exemplary embodiment of the present invention.

Referring to FIG. 3, a cell array includes a plurality of memory cells and each memory cell includes one transistor and one capacitor. The memory cells are disposed at intersections of bit lines BL1, . . . , BLn and word lines WL1, . . . , WLm, respectively. The memory cells store or output data based on voltages applied to a corresponding bit line of the bit lines BL1, . . . , BLn and a corresponding word line of the word lines WL1, . . . , WLm selected by the column decoder and row decoder (not shown).

As shown in FIG. 3, in the cell array, the bit lines BL1, . . . , BLn are formed in a first direction (this is, bit line direction) as a length direction and the word lines WL1, . . . , WLm are formed in a second direction (that is, word line direction) as a length direction so that the bit lines BL1, . . . , BLn and the word lines WL1, . . . , WLm are disposed to intersect each other. A first terminal (for example, a drain terminal) of the transistor is connected to a corresponding bit line of the bit lines BL1, . . . , BLn, a second terminal (for example, a source terminal) is connected to the capacitor, and a third terminal (for example, a gate terminal) is connected to a corresponding word line of the word lines WL1, . . . , WLm. The bit lines BL1, . . . , BLn and the word lines WL1, . . . , WLm, and the plurality of memory cells are disposed within the semiconductor cell array.

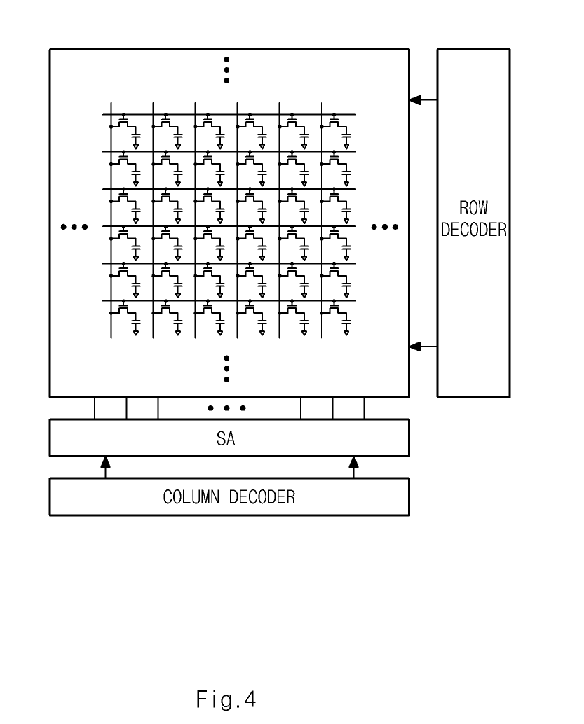

FIG. 4 is a block diagram illustrating a configuration of a semiconductor device according to an exemplary embodiment of the present invention.

Referring to FIG. 4, the semiconductor device may include a semiconductor cell array, a row decoder, a column decoder, and a sense amplifier (SA). The row decoder selects a word line corresponding to a memory cell in which a read or write operation is to be performed among word lines of the semiconductor cell array and outputs a word line select signal RS to the semiconductor cell array. The column decoder selects a bit line corresponding to a memory cell in which a read or write operation is to be performed among bit lines of the semiconductor cell array and outputs a bit line select signal CS to the semiconductor cell array. Further, the sense amplifiers sense data BDS stored in a memory cell selected by the row decoder and the column decoder.

In addition, the semiconductor device may be connected to a microprocessor or a memory controller and receives control signals such as a write enable signal (WE*), a row address strobe (RAS*) signal, and a column address strobe (CAS*) signal from the microcontroller and receives data through an input/output (I/O) circuit and stores the received data. The semiconductor device may be applied to dynamic random access memories (DRAMs), phase-change RAMs (PRAMs), magnetoresistance RAMs (MRAMs), NAND flash memories, CMOS image sensors (CISs), or the like. In particular, the semiconductor device may be applied to desktop computers, laptop computers, and servers as DRAMs. In addition, the semiconductor device may be applied to graphic memories and mobile memories. The NAND flash memory may be applied to a portable storage device such as a memory stick, a multimedia card (MMC), a secure digital (SD), a compact flash (CF), an extreme digital (xD) picture card, a universal serial bus (USB) flash device, and various digital applications such as an MP3, a portable multimedia player (PMP), a digital camera, a camcorder, a memory card, a USB, a gaming apparatus, a navigation system, a laptop computer, a desktop computer, and a mobile phone. A CIS is an imaging device serving as a kind of an electronic film in a digital apparatus and may be applied to a camera phone, a web camera, and a small-size medical photographing apparatus.

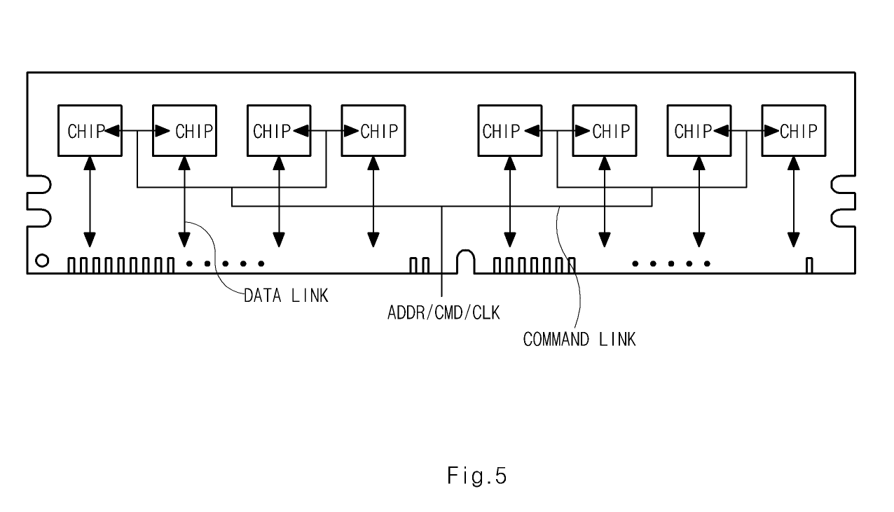

FIG. 5 is a block diagram illustrating a configuration of a semiconductor module according to an exemplary embodiment of the present invention.

Referring to FIG. 5, the semiconductor module includes a plurality of semiconductor devices mounted on a module substrate, a command link which allows the semiconductor devices to receive control signals (address signal (ADDR), command signal (CMD), clock signal (CLK)) from an external controller (not shown), and a data link which is connected to the semiconductor devices and transfers data to the semiconductor devices.

In an embodiment, the semiconductor devices may include a semiconductor device as illustrated in FIG. 3. The same command link and the data link as that used in the conventional semiconductor module or the data link and command link similar to that used in the conventional semiconductor module may be formed.

Although FIG. 5 has illustrated 8 semiconductor devices (or semiconductor chips) mounted on a front of the module substrate, the semiconductor devices may also be mounted on a rear of the module substrate in the same manner. That is, the semiconductor devices may be mounted on one side or both sides of the module substrate and the number of semiconductor devices is not limited to the number shown in FIG. 5. In addition, the material and construction of the module substrate are not specifically limited thereto.

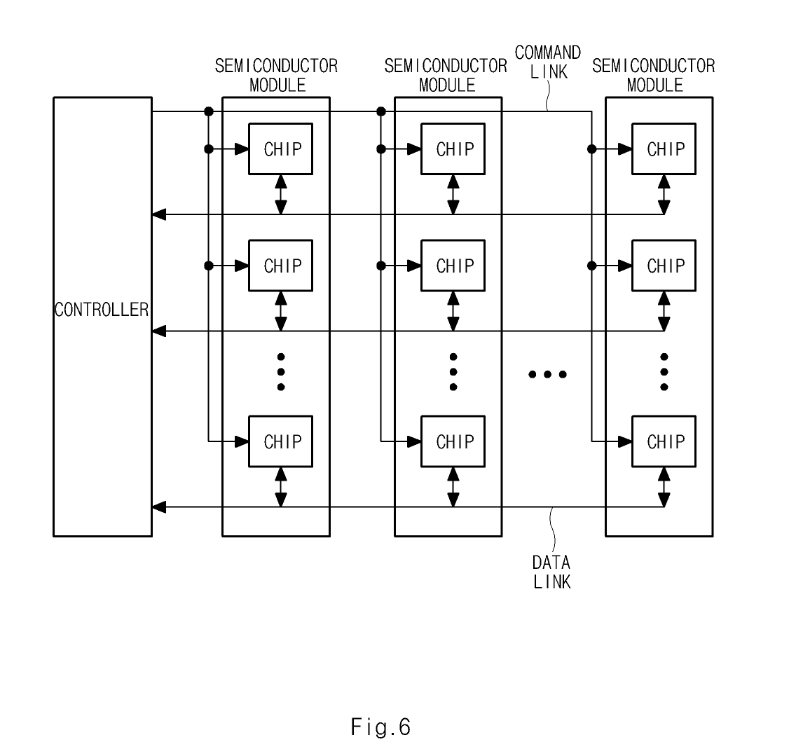

FIG. 6 is a block diagram illustrating a configuration of a semiconductor system according to an exemplary embodiment of the present invention.

Referring to FIG. 6, the semiconductor system includes at least one semiconductor module in which a plurality of semiconductor devices are mounted and a controller configured to provide a bidirectional interface between the semiconductor module and an external system (not shown) and control the semiconductor module. The controller may be formed to have the same function as or similar function to a controller configured to control an operation of a plurality of module in a conventional data processing system. Therefore, its detailed description will be omitted herein. The semiconductor module may include a semiconductor module as illustrated in FIG. 5.

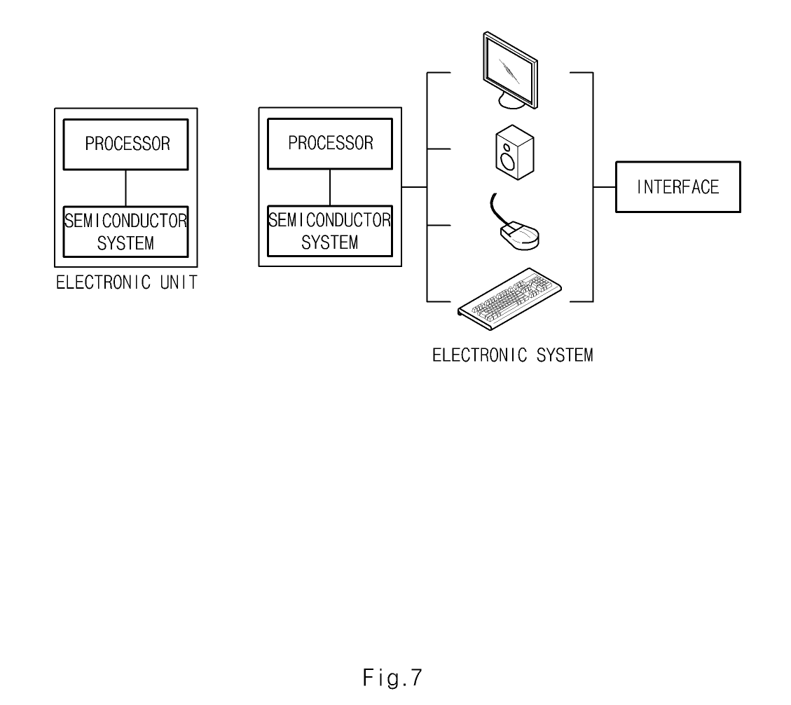

FIG. 7 is a block diagram illustrating configurations of an electronic unit and an electronic system according to an exemplary embodiment of the present invention.

Referring to the left drawing of FIG. 7, an electronic unit according to an exemplary embodiment includes a semiconductor system and a processor electrically connected to the semiconductor system. The semiconductor system may have the same configuration as the semiconductor system of FIG. 6. Here, the processor includes a central processing unit (CPU), a micro processor unit (MPU), a micro controller unit (MCU), a graphics processing unit (GPU) or a digital signal processor (DSP).

In an embodiment, the CPU or MPU has a combined form of an arithmetic logic unit (ALU), which is an arithmetic and logical operation unit, and a control unit (CU) which reads and interprets commands to control each unit. When the processor is a CPU or MPU, the electronic unit may include computer appliances or mobile appliances. Further, a GPU is a CPU for graphics, and is used to calculate numbers having a decimal point. The GPU is a processor which draws graphics on a screen in real time. When the processor is GPU, the electronic unit may include graphic appliances. A DSP is a processor that quickly converts an analog signal (for example, audio) into a digital signal, calculates the converted signal, and uses the calculated result or converts the calculated result into an analog signal again. A DSP typically calculates digital values. When the processor is a DSP, the electronic unit may include audio and video appliances.

In addition, the processor includes an accelerate processor unit (APU). The processor has a combined construction of a CPU with a GPU and serves as a graphic card.

Referring to the right drawing of FIG. 7, an electronic system includes an electric unit and at least one interface electrically connected to the electronic unit. In an embodiment, the electronic unit has the same configuration as the electronic unit of FIG. 7. The interface may include a monitor, a key board, a pointing device (mouse), a USB, a switch, a card reader, a keypad, a dispenser, a phone, a display, or a speaker. However, the present invention is not limited thereto.

As described above, according to an exemplary embodiment, after a gate pattern is formed on a semiconductor substrate, a C ion implantation process for suppressing diffusion of dopants in the semiconductor substrate is performed. Then a halo ion implantation process is performed to implant P ions. As a result, a hot carrier effect, caused by a change of a dopant profile, and degradation of GIDL characteristics can be improved.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method of manufacturing a semiconductor device, comprising:
forming a gate pattern over a semiconductor substrate;
implanting carbon ions into the semiconductor substrate; and
implanting halo ions into the semiconductor substrate, the implanting the halo ions being performed through a tilted ion implantation process.

2. The method of claim 1, wherein the implanting the C ions includes performing an ion implantation process with a dose of 1×10¹⁴ to 1×10¹⁵ ions/cm² and a beam energy of 1 keV to 15 keV.

3. The method of claim 1, wherein the implanting the C ions includes performing a tilted ion implantation process at an angle between more than 0 and no more than 20 degrees with respect to a direction orthogonal to the semiconductor substrate.

4. The method of claim 1, wherein the implanting the halo ions includes implanting phosphorus ions.

5. The method of claim 1, wherein the implanting the halo ions includes performing an ion implantation process with a dose of 1×10¹² to 1×10¹⁴ ions/cm² and a beam energy of 10 keV to 100 keV.

6. The method of claim 1, wherein the implanting the halo ions may include performing a tilted ion implantation process at an angle between more than 0 and no more than 20 degrees with respect to a direction orthogonal to the semiconductor substrate.

7. The method of claim 4, wherein the phosphorus ions are implanted into substantially all of the semiconductor substrate, except the semiconductor substrate under the gate pattern.

8. The method of claim 4, wherein the phosphorus ions are implanted into the semiconductor substrate at substantially the same level as where the carbon (C) ions is implanted.
